(19) United States
(12) Patent Application Publication
(10) Pub. No.: US 2026/0136486 A1
(43) Pub. Date: May 14, 2026

(54) FIXTURE FOR HOLDING CAPACITORS AND ELECTRIC MOTOR DRIVE WITH A FIXTURE

(71) Applicant: Danfoss Power Electronics A/S, Grästen (DK)

(72) Inventors: Denis Paja, Kolding (DK); Andreas Schultz Hermannsen, Egernsund (DK)

(21) Appl. No.: 19/380,114

(22) Filed: Nov. 5, 2025

(30) Foreign Application Priority Data
Nov. 8, 2024 (DE) 102024132723.5

(51) Int. Cl. H05K 7/02

(52) U.S. Cl. CPC H05K 7/02

(57) ABSTRACT

The present invention is directed at a fixture for an electric device such as an electric motor drive, electrolyser or frequency converter. The fixture is provided for holding capacitors and PCBAs of different sizes and/or at different positions relative to the electric device. The fixture includes at least one protruding portion with supports and preferably a wall for holding a capacitor. The fixture also includes a reception portion with a connection feature for receiving a nut of a stand-off portion, wherein the stand-off portion is provided for connecting a first PCBA such as a PCBA including large capacitors to a power PCBA and wherein the protruding portion and the reception portion are provided on a main portion of the fixture. The invention is also directed at an electric application such as an electric motor drive, electrolyser or frequency converter with a fixture for holding capacitors and PCBAs.

### CROSS-REFERENCE TO RELATED APPLICATION

This application claims foreign priority benefits under 35 U.S.C. § 119 from German Patent Application No. 102024132723.5, filed Nov. 8, 2024, the content of which is hereby incorporated by reference in its entirety.

### TECHNICAL FIELD

The present invention is directed at a fixture for an electric device such as an electric motor drive, electrolyser or frequency converter. The fixture is provided for holding capacitors and PCBAs of different sizes and/or at different positions relative to the electric device.

### BACKGROUND

Complex electric devices such as an electric motor drives, electrolysers or frequency converters comprise numerous components which must be arranged in a sensible way with respect to each other. Typical problems associated with the arrangement of the components include ensuring that different types of components do not require specific fixtures and that the components can be arranged precisely in order to minimize stresses on the components and minimize tolerances, especially with regard to the tolerance chain of electrical connections.

### SUMMARY

The aim of the present invention is to provide an improved fixture and an improved electric application with a fixture, which overcome the above problems. This aim is achieved by a fixture according to claim 1 and an electronic application according to claim 10. Advantageous embodiments are subject to the dependent claims.

According to claim 1, a fixture for an electric device such as an electric motor drive, electrolyser or frequency converter is provided. The fixture may be a holder or mounting capable of connecting various components of the electric device such that the components are maintained at a desired position, orientation and state. The presently described fixture is provided for holding capacitors and PCBAs of different sizes and/or at different positions relative to the remainder of the electric device. In particular, capacitors of different sizes may be attached to the fixture at different positions. The fixture also makes it possible to position at least two different PCBAs precisely with respect to each other.

The fixture comprises at least one protruding portion with supports and preferably a wall for holding at least one capacitor. Each protruding portion may be provided for holding one capacitor at a time. If two protruding portions are arranged next to each other, they may share a common wall between them. The capacitors may be regarded as part of the fixture.

The fixture also comprises a reception portion with a connection feature for receiving a nut of a stand-off portion, wherein the stand-off portion is provided for connecting a first PCBA to a power PCBA and wherein the protruding portion and the reception portion are provided on a main portion. The main portion of the fixture may be an approximately planar structure, which preferably extends in parallel to the planar direction of the PCBAs connected to the fixture. The stand-off portion may be provided for separating the two PCBAs and fixing them relative to each other. The stand-off portion may be oriented substantially perpendicular to the planes in which the PCBAs and/or the main portion of the fixture extend. The first PCBA may comprise substantial and heavy capacitors.

The present invention makes it possible to connect four or more different PCBA variants with preferably different capacitor variants to a single type of fixture, wherein the fixture provides vibration protection to the capacitor connections. The presently described invention therefore reduces the amount of different types of fixtures and hence offers a cost efficient solution with reduced part count, reduced requirements for production resources, reduced tooling investments, simplified production steps, reduced development time and reduced time to market.

In a preferred embodiment of the invention, the supports and the wall are oriented in a preferably circumferential direction with respect to each other, wherein the supports comprise connecting portions for connecting to the capacitor, preferably via snap fit connections. Each of the protruding portions may hence comprise a circumferentially arranged support structure for holding a preferably cylindrical capacitor. The circumferential direction of the support structure of the protruding portions may hence be referenced to the circumferential direction of the cylindrical capacitor it supports.

In another preferred embodiment of the invention, two adjacent protruding portions share the same wall and/or close connecting portions are provided closer to the main portion than the distant connecting portions.

In a particularly preferred embodiment of the invention, the close connecting portions of a given protruding portion are offset with respect to the distant connecting portions in a circumferential direction and/or each support comprises one close connecting portion and one distant connecting portion spaced apart from each other in a circumferential direction. The two connecting portions may therefore be spaced apart from each other in a circumferential and in an axial direction.

In another preferred embodiment of the invention, preferably four protruding portions are provided and oriented in a linear direction. The protruding portions may be spaced apart from each other at equal distances. Any suitable number of protruding portions may be selected within the scope of the present invention.

In another preferred embodiment of the invention, the connection feature comprises preferably three snap fit connections and three separators, all oriented in a circumferential direction with respect to each other. The connection feature may be provided radially inside the separators. The circumferential direction of these features may be referenced to the circumferential direction of the nut they are holding. The snap fit connections may be oriented such that they hold the nut against the main portion of the fixture.

In another preferred embodiment of the invention, the reception portion comprises a lead-through for accommodating a part of the stand-off portion. The lead-through may be provided in a central portion of the reception portion. The lead-through may be may be a cylindrically shaped hole. Its size may be selected such that the stand-off portion may be accommodated only partially within the lead-through.

In another preferred embodiment of the invention, the stand-off portion comprises an external thread portion and an internal thread portion, wherein the external thread portion has a smaller outer diameter than the internal thread portion, and wherein the external thread portion is screwed into the nut to set a distance between the two PCBAs. The external thread portion and the internal thread portion may be spaced apart from each other in an axial direction of the stand-off portion. The axial direction of the stand-off portion may be referenced to the at axial direction of the at least partially cylindrical shape of the stand-off portion. The axial direction of the stand-off portion may be substantially perpendicular to the main portion of the fixture.

The internal threaded portion may function as a spacer for spacing apart the two PCBAs. Axial end portions of the internal threaded portion may each abut one of the two PCBAs. The external thread portion can be screwed into the nut to a degree which provides a desired distance between the main portion and one of the two PCBAs.

In another preferred embodiment of the invention, the protruding portion extends in a direction opposite to the connection feature with respect to the main portion. The different orientation of the protruding portion and the connection feature makes it possible to provide the capacitors opposite to the PCBAs with regard to the main portion.

The invention is also directed at an electric application such as an electric motor drive, electrolyser or frequency converter with a fixture.

### BRIEF DESCRIPTION OF THE DRAWINGS

Further details and advantages of the invention are described with reference to the figures. The figures show:

FIGS. 1a, 1b: different views of an embodiment of the fixture;

FIGS. 2a, 2b: detailed views of an embodiment of the fixture with different capacitors;

FIG. 3: detailed view of reception portion;

FIG. 4: detailed sectional view of stand-off portion;

FIG. 5: detailed sectional view of two stand-off portions; and

FIG. 6: perspective view of another embodiment of the fixture.

### DETAILED DESCRIPTION

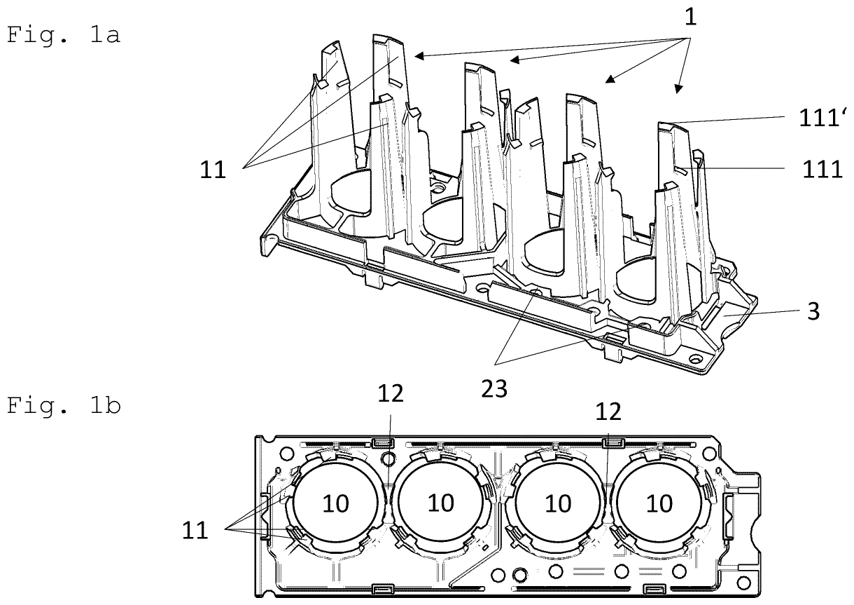

FIGS. 1a and 1b show different views of an embodiment of the fixture, FIG. 1a showing a perspective view and FIG. 1b a top view of the fixture. The fixture is provided for an electric device such as an electric motor drive, electrolyser or frequency converter, wherein the electric device is not shown in the figures. The fixture may be formed integrally from a single injection moulded component.

The fixture may be a holder or a mounting, capable of connecting various components of the electric device in a way such that the components are maintained at a desired position, orientation and state with regard to the remainder of the electric device. The fixture ensures a desired precision and rigidity of the connection between the components, the fixture and the remainder of the electric device.

The fixture comprises at least one protruding portion 1 with supports 11. In the embodiment of FIGS. 1a and 1b, four protruding portions 1 are provided, each comprising a plurality of supports 11. Four supports per protruding portion 1 may be provided.

The supports 11 may be of substantially the same shape. The supports 11 of a given protruding portion 1 may be arranged in a circular pattern and/or spaced apart from each other in a circumferential direction. The circumferential direction may be referenced to the circumference of a circle, along which the supports 11 of a given protruding portion 1 are arranged. The protruding portions 1 may be spaced apart from each other at equal distances.

As shown in FIG. 1b, a wall 12 may be provided between two adjacent protruding portions 1. If two protruding portions 1 are arranged next to each other, they may share a common wall between them. The wall 12 and the supports 11 may be provided for holding a capacitor 10. The wall 12 and the supports 11 are shown to surround a substantially cylindrical capacitor 10. The geometry of the wall 12 and/or the supports 11 may be identical or may differ from each other. Each protruding portion 1 may be provided for holding a single capacitor 10 at a time.

The supports 11 and the wall 12 are oriented in a preferably circumferential direction with respect to each other, wherein the supports 11 comprise connecting portions 111, 111′ for connecting to a capacitor 10, preferably via snap fit connections. Each of the protruding portions 1 may hence comprise a circumferentially arranged support structure for holding a preferably cylindrical capacitor 10.

The connecting portions 111, 111′ may comprise close connecting portions 111 which are provided closer to the main portion 3 than distant connecting portions 111′. The distant connecting portions 111′ may be provided at an end portion of each of the supports 11. All distant connecting portions 111′ of a given protruding portion 1 and/or of all protruding portions 1 may be spaced apart from the main portion 3 by the same larger distance and/or all close connecting portions 111 may be spaced apart from the main portion 3 by the same smaller distance. The spacing of the connecting portions 111, 111′ from the main portion 3 defines the size of the capacitor 10 that can be connected to said connecting portions 111, 111′ and therefore to the fixture.

The close connecting portions 111 of a given protruding portion 1 may be offset with respect to the distant connecting portions 111′ in a circumferential direction. Each support 11 comprises one close connecting portion 111 and one distant connecting portion 111′ spaced apart from each other in a circumferential direction. The two connecting portions 111, 111′ may therefore be spaced apart from each other in a circumferential and in an axial direction.

The fixture also comprises a reception portion 23 wherein the protruding portion 1 and the reception portion 23 are provided on the main portion 3. The main portion 3 may be a planar portion, which preferably extends in parallel to the plane in which the protruding portions 1 are aligned. The reception portion 23 is provided for receiving a connection component for connecting the fixture to a PCBA. The reception portion 23 and the protruding portion 1 may be oriented in opposite directions, such that the PCBA and the capacitors 10 can be provided on opposite sides of the main portion 3.

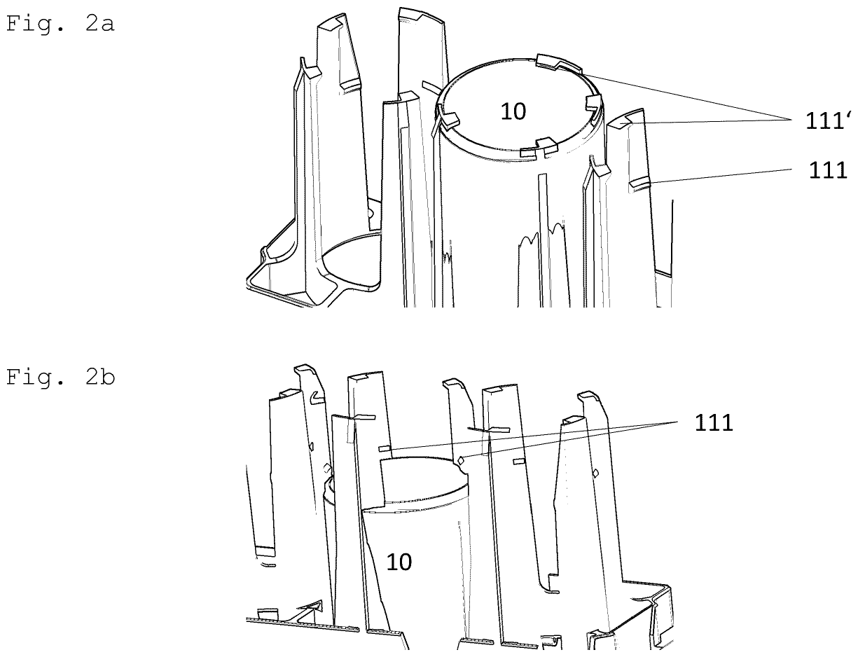

FIGS. 2a and 2b show detailed views of and embodiment of the fixture with different capacitors 10. The larger capacitor 10 of FIG. 2a is connected to and held in place by distant connecting portions 111′. The smaller capacitor 10 of FIG. 2b is connected to and held in place by close connecting portions 111. The presently described fixture is hence provided for holding capacitors 10 of different sizes and at different positions relative to the remainder of the electric device and relative to the fixture itself. In particular, capacitors 10 of different sizes i.e. lengths may be attached to the fixture at different positions.

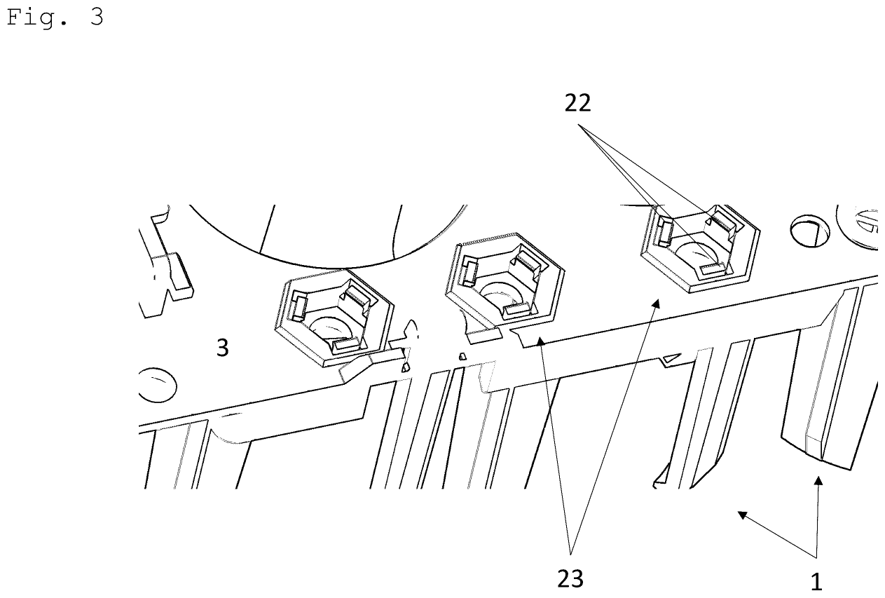

FIG. 3 is a detailed view of the main portion 3 with a number of reception portions 23, which comprise a connection feature 22. The reception portions 23 and connection feature 22 are provided for connecting the main portion 3 to PCBAs. The reception portions 23 are oriented away from the protruding portions 1. The reception portions 23 may be offset from the position of the protruding portions 1 along the planar main portion 3.

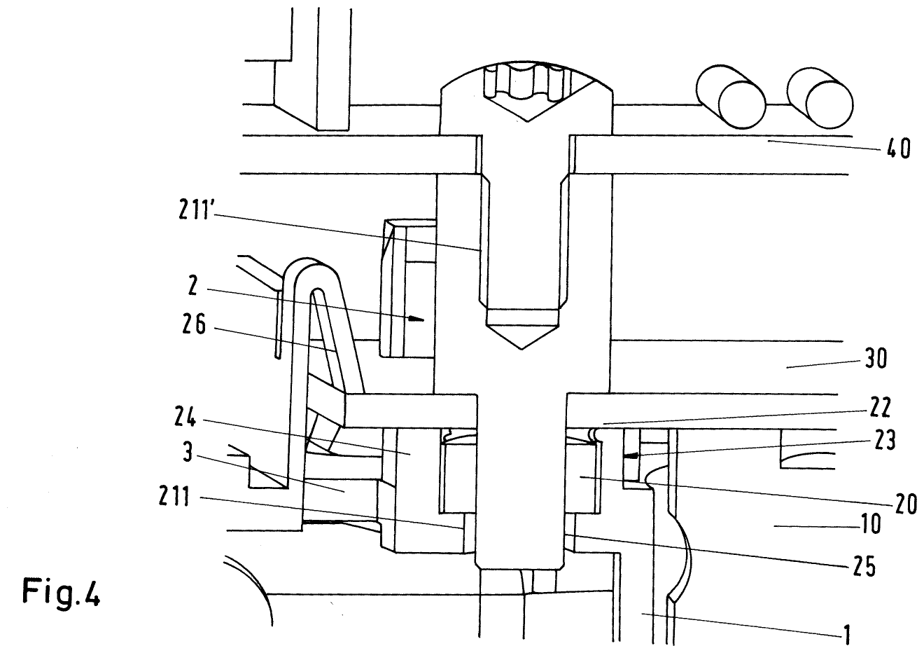

FIG. 4 is a detailed sectional view of a stand-off portion 2 provided between the main portion 3 of the fixture and two PCBAs 30, 40.

The two PCBAs 30, 40 are a first PCBA 30 and a power PCBA 40, wherein the first PCBA 30 may comprise heavy capacitors and may therefore be described as a capacitor PCBA 30 is closer to the fixture than the power PCBA 40. The capacitor PCBA 30 may be connected directly to the capacitors 10. The capacitor PCBA 30 may be sandwiched by, on the one side, reception portions 23 and/or connection features 22 and, on the other side, by one or more elastic retainer portions 26 connected to the of the main portion 3 of the fixture. The fixture may therefore be provided for positioning the capacitor PCBA 30 at a single fixed position. The one or more elastic retainer portions 26 and/or the reception portions 23 with their components, i.e. the connection features 22 and separators 24 may all or partially be formed integrally with each other.

The reception portions 23 are provided for receiving a nut 20 of the stand-off portion 2, wherein the stand-off portion 2 is provided for connecting the capacitor PCBA 30 to the power PCBA 40. The stand-off portion 2 may be provided for spacing apart the two PCBAs 30, 40 and for fixing them relative to each other.

The reception portion 23 comprises a lead-through 25 for accommodating a part of the stand-off portion 2. The lead-through 25 may be provided in a central portion of the reception portion 23. Its size may be selected such that the stand-off portion 2 may be accommodated only partially within the lead-through 25.

The stand-off portion 2 comprises an external thread portion 211 and an internal thread portion 211′, wherein the external thread portion 211 has a smaller outer diameter than the internal thread portion 211′.

The external thread portion 211 may be screwed into the nut 20 to set a distance between the two PCBAs 30, 40. The internal threaded portion 211′ may function as a spacer for spacing apart the two PCBAs 30, 40. At least one axial end portion of the internal threaded portion 211′ may abut at least one of the PCBAs 30, 40, in particular the power PCBA 40. The external thread portion 211 can be screwed into the nut 20 to a degree, which provides a desired distance between the main portion 3 and the power PCBA 40, i.e. the PCBA further away from the main portion 3 than the capacitor PCBA 30. The fixture makes it possible to position the two PCBAs 30, 40 precisely with respect to each other and with a variable distance, which is adjustable by the position of the nut 20 on the external thread portion 211.

By using dedicated stand-off portions 2, the presently described fixture may make it possible to hold PCBAs 30, 40 of different sizes and at different positions relative to the remainder of the electric device and relative to the fixture itself. In particular, different types of PCBAs 30, 40 with different thicknesses can be connected to the main portion 3 using stand-off portions 2 of different geometries. For example, the threads on the internal thread portion 211′ and/or external thread portion 211 of the stand-off portions 2 may extend over varying distances in order to space the PCBAs 30, 40 at varying distances from each other. Alternatively or additionally, the axial extension of the internal thread portion 211′ may be selected to the desired distance between the two PCBAs 30, 40. The nut 20 of the stand-off portion 2 may always be screwed onto stand-off portion 2 such that it touches the first PCBA

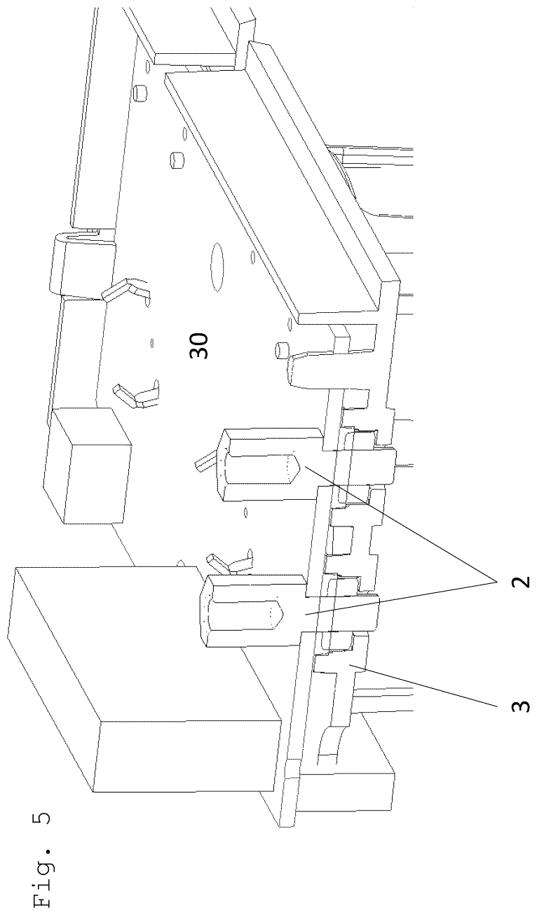

FIG. 5 is a detailed sectional view of two stand-off portions 2 provided between the main portion 3 of the fixture and the capacitor PCBA 30. Further components of the electric application containing the fixture are also shown and may include electrical components, housing portions, fastening means, connectors and controllers. The electrical device may be an electric motor drive, electrolyser or frequency converter with the presently described fixture.

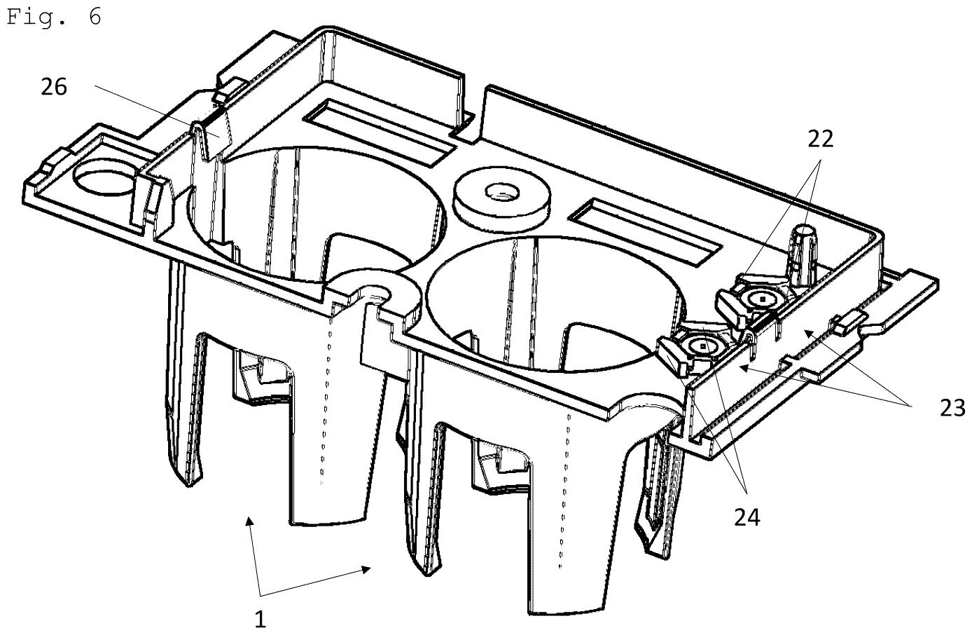

FIG. 6 is a perspective view of another embodiment of the fixture. Here, two reception portions 23 and two protruding portions 1 are provided on opposite sides of the main portion 3 of the fixture. At least one elastic retainer portions 26 is provided for pressing a PCBA towards the direction of the main portion 3. The PCBA is not shown in the figure.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A fixture or an electric device such as an electric motor drive, electrolyser or frequency converter for holding capacitors and PCBAs of different sizes and/or at different positions, comprising at least one protruding portion with supports and preferably a wall for holding a capacitor and a reception portion with a connection feature for receiving a nut of a stand-off portion, wherein the stand-off portion is provided for connecting a first PCBA to a power PCBA and wherein the protruding portion and the reception portion are provided on a main portion.

2. The fixture according to claim 1, wherein the supports and the wall are oriented in a preferably circumferential direction with respect to each other, wherein the supports comprise connecting portions for connecting to a capacitor, preferably via snap fit connections.

3. The fixture according to claim 2, wherein two adjacent protruding portions share the same wall and/or that close connecting portions are provided closer to the main portion than the distant connecting portions.

4. The fixture according to claim 3, wherein the close connecting portions of a given protruding portion are offset with respect to the distant connecting portions in a circumferential direction and/or that each support comprises one close connecting portion and one distant connecting portion spaced apart from each other in a circumferential direction.

5. The fixture according to claim 1, wherein preferably four protruding portions are provided and oriented in a linear direction.

6. The fixture according to claim 1, wherein the connection feature comprises preferably three snap fit connections and three separators, all oriented in a circumferential direction with respect to each other.

7. The fixture according to claim 1, wherein the reception portion comprises a lead-through for accommodating a part of the stand-off portion.

8. The fixture according to claim 7, wherein the stand-off portion comprises an external thread portion and an internal thread portion wherein the external thread portion has a smaller outer diameter than the internal thread portion and wherein the external thread portion is screwed into the nut to set a distance between the two PCBAs.

9. The fixture according to claim 1, wherein the protruding portion extends in a direction opposite to the connection feature with respect to the main portion.

10. An electric application such as an electric motor drive, electrolyser or frequency converter with a fixture according to claim 1.
